(19) United States
(12) Patent Application Publication
(10) Pub. No.: US 2026/0305384 A1
(43) Pub. Date: Oct. 1, 2026

(54) DUAL DIE DEVICE WITH CONDUCTIVE PLATE SUBSTRATE CONNECTION

(71) Applicant: Texas Instruments Incorporated, Dallas, TX (US)

(72) Inventors: Woochan Kim, San Jose, CA (US); Makoto Shibuya, Tokyo (LP); Nathan Schemm, Rowlett, TX (US); Sahana Sriraj, Allen, TX (US); Abha Kasper, Dallas, TX (US)

(21) Appl. No.: 19/095,629

(22) Filed: Mar. 31, 2025

(51) Int. Cl. H10W 70/40; H10W 90/00

(52) U.S. Cl. CPC H10W 70/465; H10W 70/411; H10W 70/429; H10W 70/481; H10W 90/811

(57) ABSTRACT

An electronic device includes a first semiconductor die having a first side, an opposite second side, and a first terminal along the first side, the second side of the first semiconductor die electrically connected to a conductive plate, a second semiconductor die having a first side, an opposite second side, and a second terminal along the first side, the second side of the second semiconductor die electrically connected to the conductive plate, and a bond wire that electrically connects the first and second terminals.

### BACKGROUND

Bidirectional transistors can be used for matrix converters, grid-tie converters or other power conversion systems. Some bidirectional transistors, such as gallium nitride (GaN) monolithic bidirectional switch (MBS) devices, can suffer from switching with substrate voltage-induced backgating effects.

### SUMMARY

In one aspect, an electronic device includes first and second semiconductor dies and a bond wire. The first semiconductor die has opposite first and second sides and a first terminal along the first side, and the second side of the first semiconductor die is electrically connected to a conductive plate. The second semiconductor die has opposite first and second sides and a second terminal along the first side, the second side of the second semiconductor die is electrically connected to the conductive plate. The bond wire electrically connects the first and second terminals.

In another aspect, an electronic device includes a first semiconductor die having a gallium nitride substrate with a first side and an opposite second side attached to a conductive plate by a first conductive adhesive, a second semiconductor die having a silicon substrate with a first side and an opposite second side attached to the conductive plate by a second conductive adhesive; and an electrical connection between a first conductive feature on the first side of the first semiconductor die and a second conductive feature on the first side of the second semiconductor die.

In another aspect, a system includes a circuit board, and an electronic device mounted to the circuit board. The electronic device includes first and second semiconductor dies and a bond wire, the first semiconductor die having opposite first and second sides and a first terminal along the first side, and the second side of the first semiconductor die being electrically connected to a conductive plate. The second semiconductor die has opposite first and second sides and a second terminal along the first side, the second side of the second semiconductor die is electrically connected to the conductive plate. The bond wire electrically connects the first and second terminals.

In a further aspect, a method of fabricating an electronic device includes attaching a first side of a first semiconductor die to a lead frame, attaching a conductive plate to a second side of the first semiconductor die, attaching a second side of a second semiconductor die to the conductive plate, and forming an electrical connection between a first terminal along the first side of the first semiconductor die and a second terminal along a first side of the second semiconductor die.

### BRIEF DESCRIPTION OF THE DRAWINGS

FIG. 1 is a bottom perspective view of an electronic device with first and second semiconductor dies with substrates electrically connected to a metal plate.

FIG. 1A is a top plan view of the electronic device of FIG. 1.

FIG. 1B is a sectional end elevation view of the electronic device taken along line 1B-1B of FIGS. 1 and 1A.

FIG. 1C is a sectional end elevation view of the electronic device taken along line 1C-1C of FIGS. 1 and 1A.

FIG. 1D is a sectional side elevation view of the electronic device taken along line 1D-1D of FIGS. 1 and 1A.

FIG. 1E is a schematic diagram showing components of the first and second semiconductor dies with substrates electrically connected to a metal plate.

FIG. 1F is a system diagram of a grid tie converter with two instances of the electronic device of FIGS. 1-1E.

FIG. 2 is a flow diagram of a method of fabricating an electronic device.

FIGS. 3-13 are partial sectional views of the electronic device of FIGS. 1-1E undergoing fabrication processing according to the method of FIG. 2.

### DETAILED DESCRIPTION

In the drawings, like reference numerals refer to like elements throughout, and the various features are not necessarily drawn to scale. Also, the term "couple" or "couples" includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms "including", "includes", "having", "has", "with", or variants thereof are intended to be inclusive in a manner similar to the term "comprising", and thus should be interpreted to mean "including, but not limited to".

Unless otherwise stated, “about,” “approximately,” or “substantially” preceding a value means +/- 10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, sides, etc., for ease of description in connection with a particular drawing, where such are not to be construed as limiting with respect to the claims. Various structures and methods of the present disclosure may be beneficially applied to an electronic apparatus such as an integrated circuit and manufacturing electronic devices. While such examples may be expected to provide various improvements, no particular result is a requirement of the present disclosure unless explicitly recited in a particular claim.

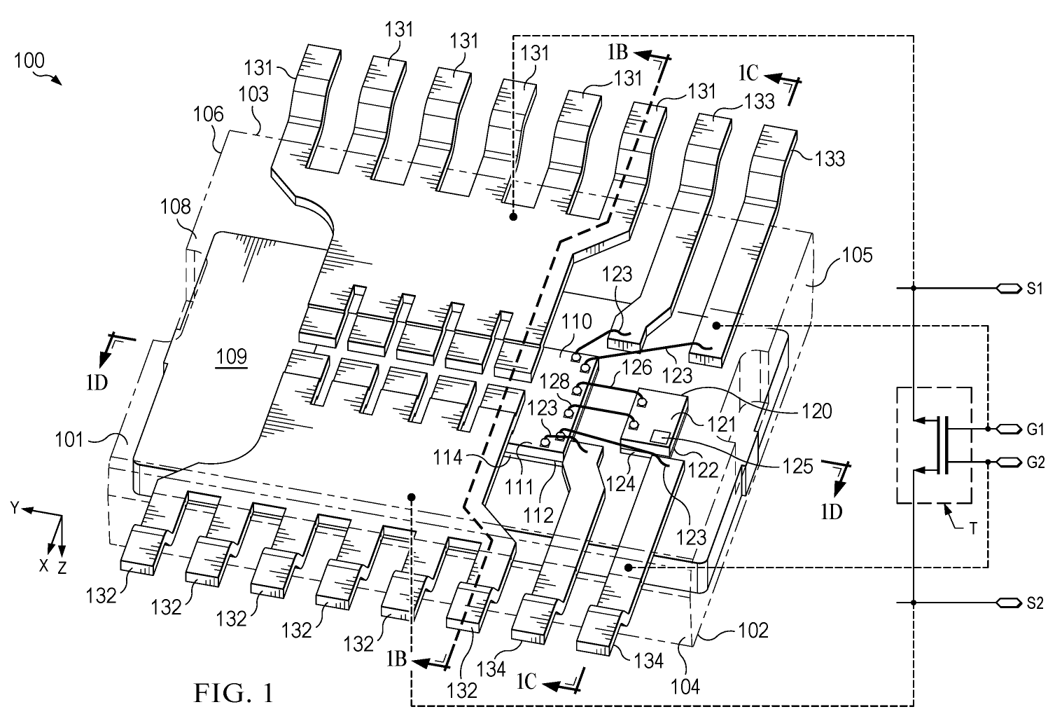

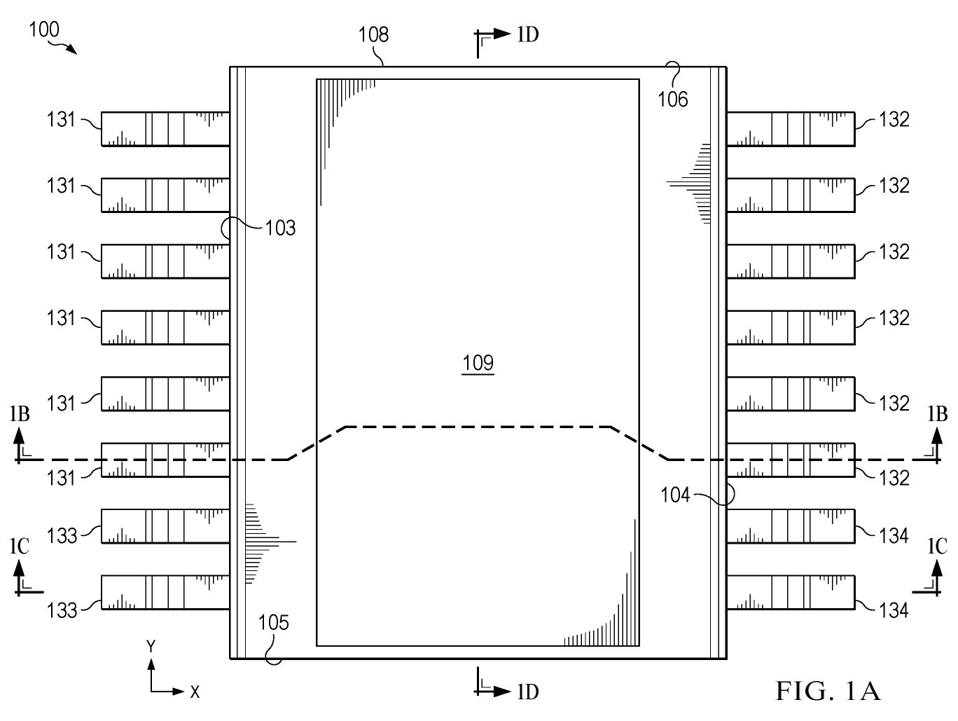

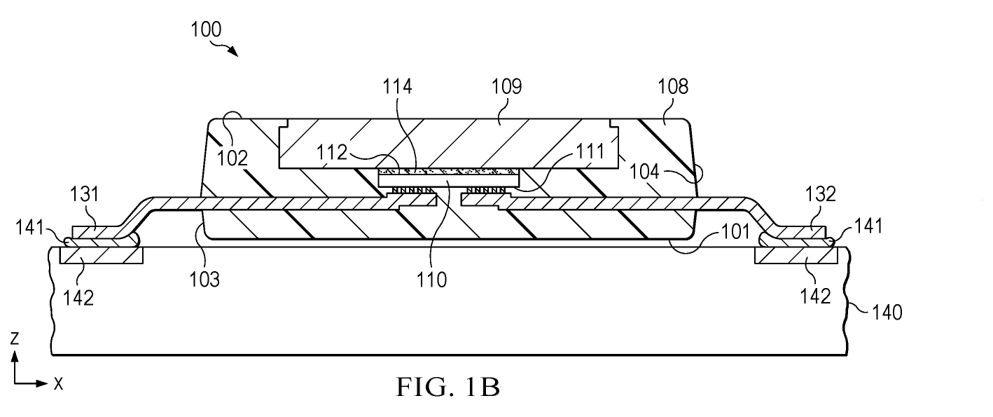

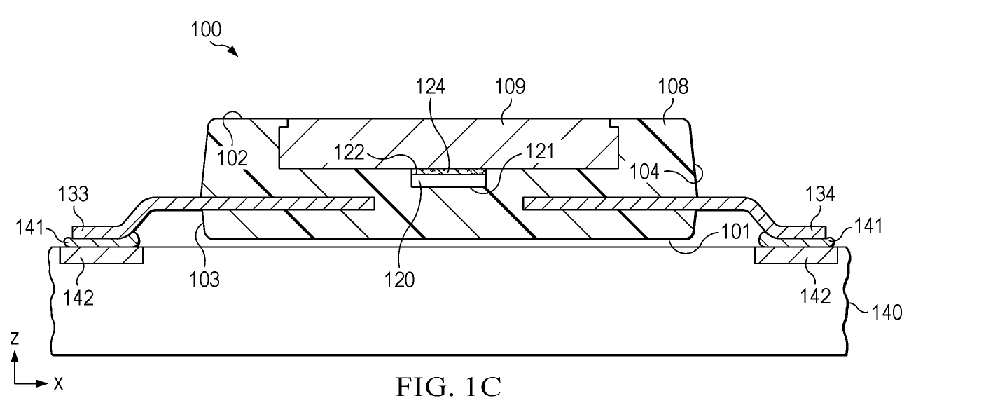

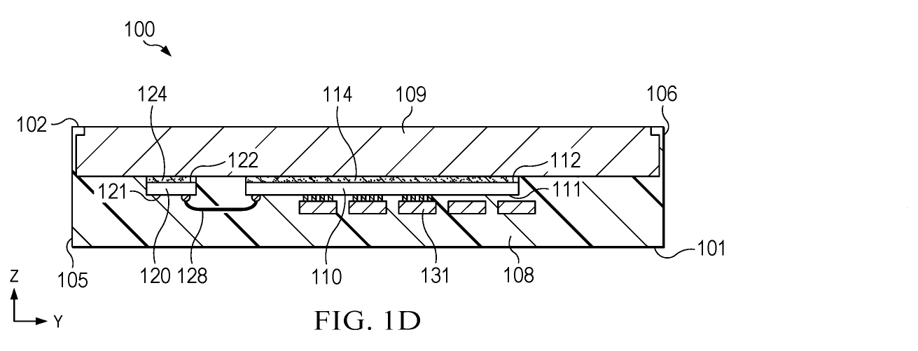

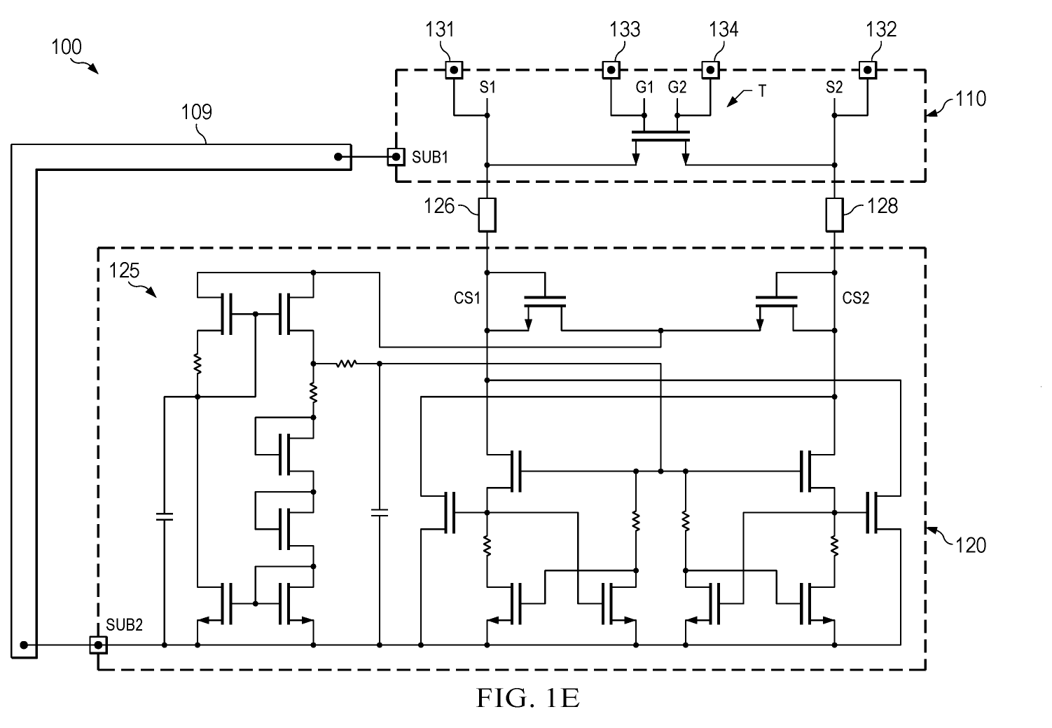

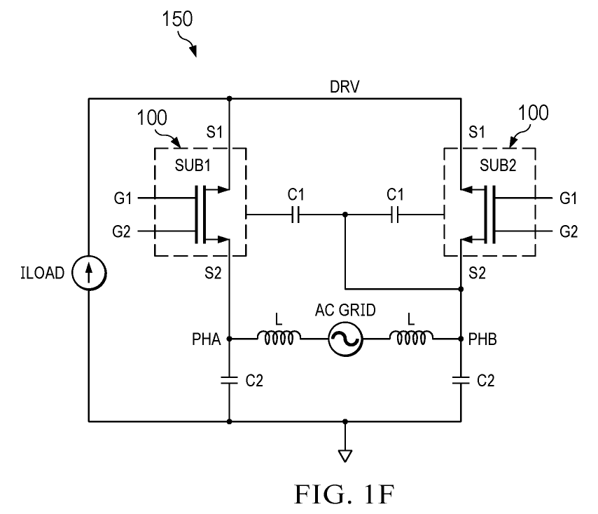

Referring to FIGS. 1-1F, FIGS. 1-1D show an example electronic device 100 with a conductive plate 109 that provides substrate connections for first and second semiconductor dies 110 and 120. The conductive plate 109 can also be referred to as a heat slug. FIG. 1 shows a bottom perspective view of the electronic device 100, FIG. 1A shows a top view, and FIGS. 1B-1D show section views along the respective lines 1B-1B, 1C-1C and 1D-1D of FIGS. 1 and 1A. FIG. 1E schematically illustrates components of the first and second semiconductor dies 110 and 120 with substrates electrically connected to the metal plate 109, and FIG. 1F shows an example grid tie power converter system with two instances of the electronic device 100 connected in a half bridge configuration.

The electronic device 100 is shown in FIGS. 1-1D in an example position in a three-dimensional space with respective first, second, and third mutually orthogonal directions X (FIGS. 1-1C), Y (FIGS. 1 and 1A) and Z (FIGS. 1 and 1B-1D). The electronic device 100 includes opposite first and second (e.g., bottom and top) sides 101 and 102 (FIGS. 1 and 1B-1D) that are spaced apart from one another along the third direction Z. The electronic device 100 also includes lateral third and fourth sides 103 and 104 (FIGS. 1-1C) that are spaced apart from one another along the first direction X, and lateral fifth and sixth sides 105 and 106 (FIGS. 1, 1A and 1D) that are spaced apart from one another along the second direction Y.

The electronic device includes a package structure 108 (e.g., a molded plastic or ceramic structure) that encloses the first semiconductor die 110, the second semiconductor die 120 and bond wires 123, 126 and 128 that are described further below. In the illustrated example, the top side of the conductive plate 109 is exposed outside the package structure 108 along the second side 102, for example, to facilitate heat removal from the circuitry of the respective first and second semiconductor dies 110 and 120. The conductive plate 109 can be any electrically conductive material, for example a conductive metal, such as including copper, aluminum, etc. In use, the exposed top side of the conductive plate 109 can help transfer heat to the ambient of the electronic device 100. In certain implementations, an external heat sink (not shown) can be attached to the exposed top side of the conductive plate 109.

As schematically illustrated in FIGS. 1 and 1E first semiconductor die 110 includes a bidirectional transistor T (e.g., a gallium nitride monolithic bidirectional switch or MBS). The example bidirectional transistor T includes a first source terminal S1 (also referred to as a first terminal), a first gate terminal G1, a second gate terminal G2, and a second source terminal S2. The second semiconductor die 120 in this example includes a substrate current steering circuit 125 with a schematically illustrated example shown in FIG. 1E. The current steering circuit 125 is operatively coupled with the bidirectional transistor of the first semiconductor die 110 to mitigate substrate voltage-induced backdating effects in operation of the bidirectional transistor.

FIG. 1E schematically illustrates the electrical interconnection of the bidirectional transistor of the first semiconductor die 110 to the current steering circuit 125 of the second semiconductor die 120. In this example, the substrates of the respective first and second semiconductor dies 110 and 120 are individually electrically connected to the conductive plate 109 by corresponding conductive die attach film layers 114 (FIGS. 1, 1B and 1D) and 124 (FIGS. 1 and 1C). The first source terminal S1 of the transistor T is coupled to a first current steering circuit input terminal CS1 (also referred to as a first input terminal) by a first bond wire 126 (also shown in FIG. 1), and the second source terminal S2 is coupled to a second current steering circuit input terminal CS2 (also referred to as a second input terminal) by a second bond wire 128 (also shown in FIGS. 1 and 1D).

The first semiconductor die 110 has a first side 111 (e.g., bottom side shown in FIGS. 1, 1B, and 1D) and an opposite second side 112 (e.g., top side). The first and second source terminals S1 and S2 are exposed along the first side 111 of the first semiconductor die 110 and are connected by respective bond wires 126 and 128 to the second semiconductor die 120 as shown in FIGS. 1 and 1E. The first semiconductor die 110 in the illustrated example has a gallium nitride (GaN) substrate (e.g., labeled “SUB1” in FIG. 1E) that extends to the second side 112, and which is attached to the conductive plate 109 by the first conductive adhesive 114 shown in FIGS. 1, 1B and 1D.

The second semiconductor die 120 has a first side 121 (e.g., bottom side shown in FIGS. 1, 1C, and 1D) and an opposite second side 122 (e.g., top side). The second semiconductor die 120 has the current steering circuit input terminals CS1 and CS2 along the first side 121. The second side 122 of the second semiconductor die 120 is electrically connected to the conductive plate 109 by the second conductive adhesive 124 as shown in FIGS. 1 and 1C. The second semiconductor die 120 in the illustrated example has a silicon (Si) substrate (e.g., labeled “SUB2” in FIG. 1E) that extends to the second side 122 and is attached to the conductive plate 109 by the second conductive adhesive 124 shown in FIGS. 1, 1C and 1D.

As further shown in FIGS. 1, 1A, and 1E, the electronic device includes conductive leads 131, 132, 133, and 134 (e.g., conductive metal, such as including copper, aluminum, etc.). The illustrated example has gullwing shaped leads 131-134 with interior portions enclosed by the package structure 108 and outer portions that extend outward from the third and fourth sides 103, 104 of the package structure 108 to allow insertion into a socket or soldering to conductive features 142 of a printed circuit board 140 (PCB, FIGS. 1B and 1C) using solder 141.

The electronic device 100 also includes additional bond wires 123 (FIG. 1) forming connections between corresponding conductive features or terminals of the first semiconductor die 110 and corresponding leads 133 and 134. The illustrated example has six instances of the first lead 131 (e.g., FIGS. 1 and 1A) along the third side 103, which are electrically coupled to the first source terminal S1 of the transistor T (schematically shown in FIG. 1E). The leads 131 in this example are formed of a contiguous metal structure (e.g., copper, aluminum, etc.) that includes flip chip solder connections (e.g., FIG. 1B) to corresponding first source terminals along the first side 111 of the first semiconductor die 110. Six instances of the second lead 132 extend outwardly from the fourth side 104 and provide external connection to the second source terminal S2 as shown in FIGS. 1, 1A, and 1E. The leads 132 in this example are formed of a second contiguous metal structure (e.g., FIG. 1) with flip chip solder connections (e.g., FIG. 1B) to corresponding second source terminals (e.g., S2 in FIG. 1E) along the first side 111 of the first semiconductor die 110.

As further shown in FIG. 1, two instances of the third lead 133 (FIG. 1) extend along the third side 103 and provide external connection by corresponding bond wires 123 to further terminals along the first side 111 of the first semiconductor die 110. In the illustrated example, the third leads 133 are electrically coupled to the first gate terminal G1 of the transistor T as further schematically illustrated in FIG. 1E. In addition, two instances of the fourth lead 134 (FIG. 1) extend along the third side 103 and provide external connection by corresponding bond wires 123 to other terminals along the first side 111 of the first semiconductor die 110 to provide external connections for the second gate terminal G2 (FIG. 1E).

As shown in FIGS. 1 and 1E, the second semiconductor die 120 includes the current steering circuit 125 with the first and second input terminals CS1 and CS2 along the first side 121 of the second semiconductor die 120, and the second substrate connection SUB2 to the second side 122 of the second semiconductor die 120, which is electrically connected to the first substrate connection SUB1 of the first semiconductor die 110. The first bond wire 126 electrically connects the first source terminal S1 of the first semiconductor die 110 to the first input terminal CS1 of the current steering circuit 125 of the second semiconductor die 120. The second bond wire 128 electrically connects the second source terminal S2 of the first semiconductor die 110 to the second input terminal CS2 of the second semiconductor die 120. The electrical connections by the bond wires 126 and 128 between conductive features of the first and second semiconductor dies 110 and 120 provide first and second source connections of the bidirectional transistor T to the current steering input terminal CS1 and CS2 of the second semiconductor die 120. Other forms and types of electrical connections between the corresponding source terminals S1, S2 and the current steering input terminals CS1, CS2 can be used in other examples. In addition, the substrates (SUB1 and SUB2) of the semiconductor dies 110 and 120 are electrically connected to one another by the conductive plate 109.

In operation, the current steering circuit 125 advantageously mitigates substrate voltage-induced backgating effects in operation of the bidirectional transistor T. Any suitable current steering circuit 125 can be used, where FIG. 1E shows one possible example. The current steering circuit 125 has a connection to the substrate of the gallium nitride first semiconductor die 110 by the conductive die attach film layers 114 and 124 and by the conductive plate 109. The current steering circuit 125 helps to mitigate or manage substrate voltage swings relative to the first and second transistor source terminals S1 and S2 during switching operation to avoid backgating. Reducing back gating, in turn, reduces the on state resistance of the bidirectional transistor T.

In addition to the benefits provided by the current steering circuit 125, the illustrated example advantageously reduces cost and complexity. In particular, the substrate current steering circuit 125 is fabricated in an inexpensive silicon die 120. Incorporating corresponding substrate current steering circuitry in a more expensive gallium nitride die (e.g., in the first semiconductor die 110) could significantly increase the size of the first semiconductor die 110. In addition, the illustrated example advantageously provides electrical connection of the substrate connections (e.g., SUB2) of the current steering circuitry 125 to the substrate connection (SUB1) of the first semiconductor die 110 by connection to the conductive plate 109 using the conductive die attach material layers 114 and 124 (FIGS. 1 and 1B-1D). This configuration provides significant cost and complexity savings compared to die topside connections (e.g., using vias extending vertically from the gallium nitride substrate along or near the second side 112 of the first semiconductor die 110 to the top or first side 111) to provide an interconnection by a bond wire or other electrical connection to the second semiconductor die 120. In this regard, certain high voltage gallium nitride fabrication processes and structures cannot easily provide conductive vias to the gallium nitride substrate using an epitaxial via processes or other techniques. The illustrated implementation allows reduction in the size and area of the first semiconductor die 110, and the cost savings associated with the smaller gallium nitride semiconductor die 110 is expected to exceed the cost of providing the second semiconductor die 120.

FIG. 1F shows an example grid tie converter system 150 with two instances of the bidirectional gallium nitride transistor T electronic device 100 described above in connection with FIGS. 1-1E. Each instance of the electronic device 100 in the system 150 of FIG. 1F includes first and second source terminals S1, S2 and first and second gate terminals G1 and G2, as well as corresponding substrate connections (e.g., labeled “SUB1” and “SUB2”) for the corresponding first and second instances of the electronic device 100. The example electronic device 100 can be used in other systems, such as power converters, high voltage transistors switching circuits, etc.

In one implementation, the electronic devices 100 are mounted to a circuit board, for example, with the leads of each of the electronic devices 100 (e.g., leads 131-134 in FIGS. 1, 1A and 1E above) soldered to a circuit board (e.g., circuit board 140 in FIGS. 1B and 1C) of the system 150. The example system 150 includes two instances of the electronic device 100 connected in a half bridge grid tied converter circuit, each instance of the electronic device 100 including a bidirectional transistor with two source terminals S1, S2 and two gate terminals G1, G2, as well as a corresponding substrate connection. The half bridge converter configuration has the first source terminals S1 of each instance of the electronic device 100 coupled to a load by a drive node labeled “DRV” that receives a load current ILOAD from an AC grid (e.g., labeled “AC-GRID”). The converter 150 includes inductors L coupled between the AC grid and phase lines PHA and PHB connected to the corresponding second source terminals S2 of the respective instances of the electronic device 100. The converter system 150 also includes respective instances of a first capacitor C1 coupled between the corresponding electronic device substrate connections SUB1 and SUB2 and a jointing node, which is connected to the second source terminal S2 of the second instance of the electronic device 100. The individual phase lines PHA and PHB are connected to a reference node by a respective instance of a second capacitor C2.

In operation, in one example, the grid tie converter 150 operates in two modes depending on the corresponding half cycle of the AC grid power. In a first (e.g., positive) half cycle where the voltage of PHA is greater than the voltage of PHB, the first instance of the electronic device 100 (e.g., on the left in FIG. 1F) has a positive gate voltage connected to the second gate terminal G2 and the first gate terminal G1 of the first instance of the electronic device 100 is pulse width modulated. During this first half cycle, a positive gate voltage is connected to the first gate terminal G1 of the second instance of the electronic device 100 (e.g., on the right in FIG. 1F), and the second gate terminal G2 of the second instance of the electronic device 100 is pulse width modulated. This operation in the first half cycle conducts a forward current through the first instance of the electronic device 100 (e.g., from the first source terminal S1 to the second source terminal S2) and conducts a reverse current through the second instance of the electronic device 100 (e.g., from the second source terminal S2 to the first source terminal S1).

In a second (e.g., negative) half cycle, the voltage of PHB is greater than the voltage of PHA. In the second half cycle, the first instance of the electronic device 100 (e.g., on the left in FIG. 1F) has a positive gate voltage connected to the first gate terminal G1 and the second gate terminal G2 of the first instance of the electronic device 100 is pulse width modulated. During this second half cycle, a positive gate voltage is connected to the second gate terminal G2 of the second instance of the electronic device 100 (e.g., on the right in FIG. 1F), and the first gate terminal G1 of the second instance of the electronic device 100 is pulse width modulated. The second half cycle conducts a reverse current through the first instance of the electronic device 100 (e.g., from the second source terminal S2 to the first source terminal S1) and conducts a forward current through the second instance of the electronic device 100 (e.g., from first source terminal S12 the second source terminal S2).

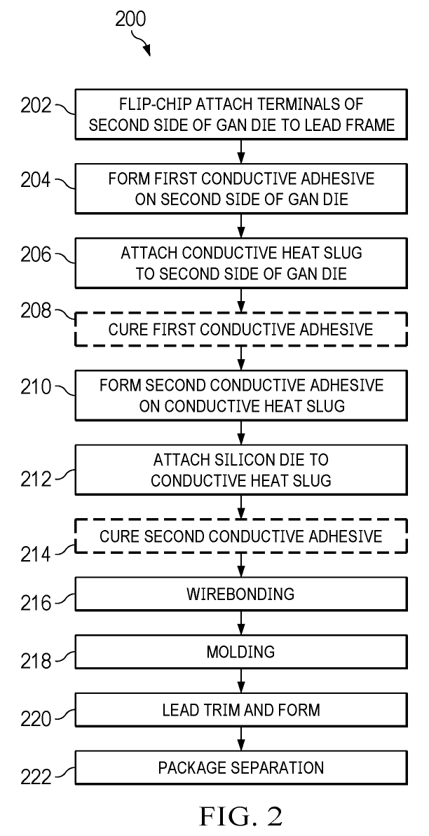

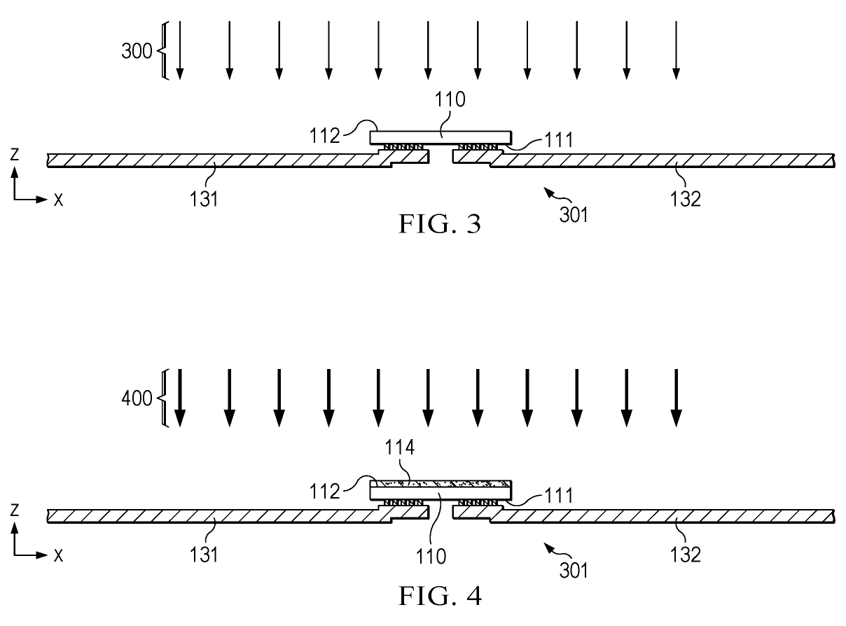

Referring also to FIGS. 2-13, FIG. 2 shows an example method 200 of fabricating an electronic device, and FIGS. 3-13 shows the example electronic device 100 undergoing fabrication processing according to the method 200. The method 200 begins at 202 in FIG. 2 with flip chip attaching the first semiconductor die to a lead frame. FIG. 3 shows one example beginning with a starting lead frame 301 array panel or strip having multiple rows and columns of unit areas, each corresponding to a prospective electronic device 100, where FIG. 3 shows one example unit area. The lead frame 301 (e.g., copper or other suitable conductive material) in this example includes prospective lead features labeled 131 and 132 corresponding to the subsequently trimmed and formed leads of the electronic device 100 being fabricated (e.g., along a section line corresponding to section line 1B-1B in FIG. 1 above). A process 300 is performed that flip chip attaches the first semiconductor die 110 to the prospective lead portions 131, 132 of the starting lead frame 301 using flip chip soldering equipment and techniques (not shown). In one example, the process 300 includes providing solder on the tips of conductive pillars or other features along the first side 111 of the first semiconductor die 110 (e.g., for the first and second source connections S1 and S2), and attaching the first semiconductor die 110 to the illustrated unit area of the lead frame 301 to provide first source connections to the prospective first lead 131 and second source connections to the second prospective lead 132, using automated pick and place equipment (not shown). The process 300 in one example includes further thermal reflow processing to reflow the solder and form solder connections from the terminals of the first semiconductor die 110 to the respective portions of the lead frame 301.

The method 200 continues at 204 in FIG. 2 with forming the first conductive adhesive on the second side 112 of the first semiconductor die 110. FIG. 4 shows one example, in which a formation process 400 is performed that forms the first conductive die attach adhesive 114 along at least a portion of the second side 112 of the first semiconductor die 110 in each unit area of the lead frame panel array 301. Any suitable adhesive formation process 400 can be used, for example, including printing, dispensing, etc.

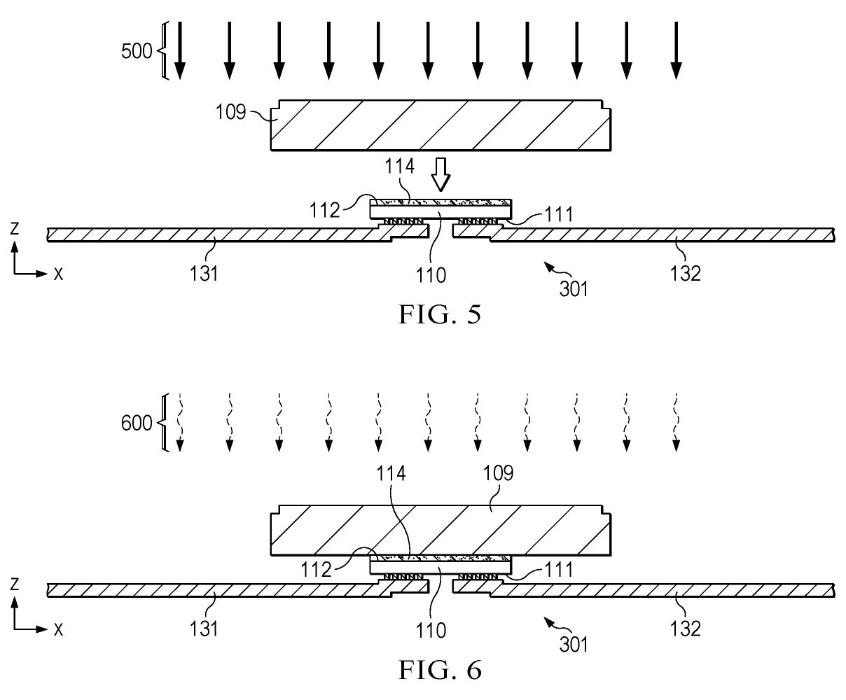

The method 200 continues at 206 in FIG. 2 with attaching a conductive plate (e.g., heat slug) to the second side 112 of the first semiconductor die 110. FIG. 5 shows one example, in which an attachment process 500 is performed that attaches the conductive plate 109 to the conductive adhesive 114 on the second side 112 of the first semiconductor die 110 in each unit area of the lead frame panel array 301. Any suitable attachment process 500 can be used, such as operating automated pick and place equipment (not shown) to attach an instance of the conductive plate 109 to the second side 112 of the first semiconductor die 110 in each unit area.

In one example, the method 200 includes curing the first conductive adhesive 114 at 208 in FIG. 2. FIG. 6 shows one example, in which a thermal curing process 600 is performed that cures the first conductive adhesive 114 to provide an electrical and mechanical connection of the conductive plate 109 to the second side 112 of the first semiconductor die 110 that electrically connects the substrate or backside of the first semiconductor die 110 (e.g., gallium nitride substrate, SUB1 in FIG. 1E above) to the conductive plate 109. In another example, the first conductive adhesive 114 can be cured by other means (e.g., UV curing, etc.). In a further example, the curing at 208 can be omitted.

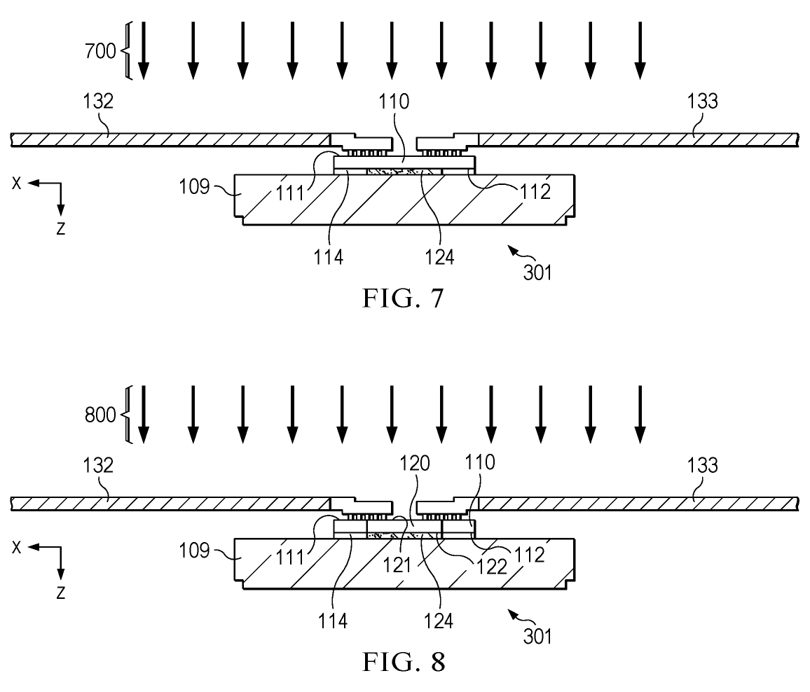

At 210 in FIG. 2, the method 200 continues with forming the second conductive adhesive 124 on the conductive plate 109. FIG. 7 shows one example, in which a formation process 700 is performed that forms the second conductive adhesive 124 on a select portion of the conductive plate 109 corresponding to the prospective location of the second semiconductor die 120. Any suitable adhesive formation process 700 can be used, for example, printing, dispensing, etc.

The method 200 continues at 212 in FIG. 2 with attaching the second side 122 of an instance of the second semiconductor die 120 to the conductive plate 109 in each unit area of the panel array structure. FIG. 8 shows one example, in which an attachment process 800 is performed (e.g., using automated pick and place equipment, not shown). The attachment process 800 attaches the second side 122 of the second semiconductor die 120 to a second conductive adhesive 124 on the conductive plate 109.

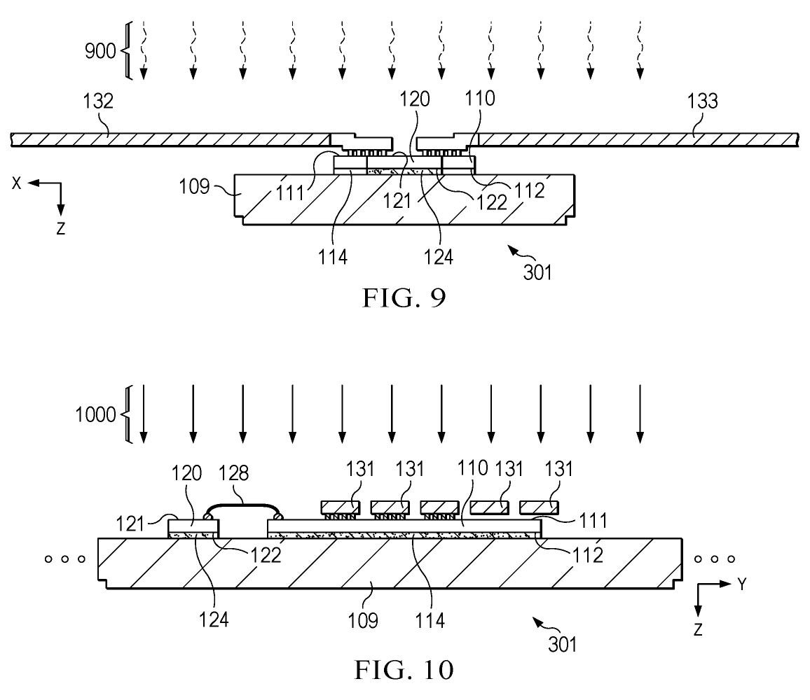

In one example, the method 200 includes curing the second conductive adhesive 124 at 214 in FIG. 2. FIG. 9 shows one example, in which a thermal curing process 900 is performed that cures the second conductive adhesive 124 to provide an electrical and mechanical connection of the conductive plate 109 to the second side 122 of the second semiconductor die 120 that electrically connects the substrate or backside of the second semiconductor die 120 (e.g., silicon substrate, SUB2 in FIG. 1E above) to the conductive plate 109. In another example, the second conductive adhesive 124 can be cured by another process (e.g., UV curing, etc.). In this or another example, the curing at 214 in FIG. 2 can be used to concurrently cure the first conductive adhesive 114, for example, where the optional curing at 208 is omitted. In a further example, the curing at 214 can be omitted.

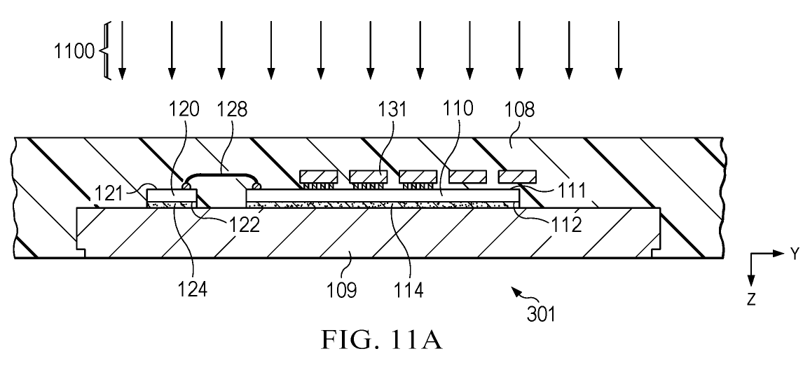

The method 200 continues at 216 in FIG. 2 with forming electrical connections between terminals and/or conductive features of one or more of the semiconductor dies 110, 120 and the prospective lead portions 131-134 in each unit area of the lead frame panel array 301. FIG. 10 shows one example, in which a wirebonding process 1000 is performed that forms the bond wire 128 that connects the second source terminal S2 of the first semiconductor die 110 to the second current steering input terminal CS2 of the second semiconductor die 120. The wirebonding process 1000 in this example also forms the other bond wires 123 and 126 (e.g., FIG. 1 and 1E above) to interconnect the semiconductor dies 110 and 120 and the prospective lead portions 131-134 in each unit area of the lead frame panel array 301. In other examples, different forms of electrical interconnection processes and/or techniques can be used at 216 (e.g., flip chip soldering, attachment and soldering of conductive metal clips, etc.) alone or in combination with wire bonding.

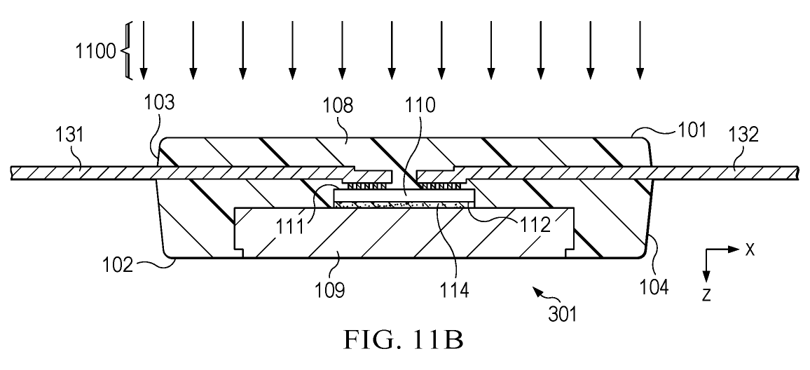

At 218 in FIG. 2, the method 200 continues with forming a package structure (e.g., package structure 108 above). FIGS. 11A and 11B show one example, in which a molding process 1100 is performed that forms the example molded package structure 108 that encloses the first semiconductor die 110, the second semiconductor die 120 and the bond wire electrical connections 123, 126, and 128. In one example, the molding process 1100 uses a mold (not shown) with a single cavity for each individual unit area of the lead frame panel array structure 301. In another implementation, the mold can have a shared cavity that extends across multiple unit areas of the lead frame 301, for example, along rows or columns of the panel array structure of the lead frame 301. In another implementation, a single mold cavity can be used to create a molded package structure 108 that extends across multiple unit areas of the lead frame 301. In the illustrated example, the molding process 1100 creates a single shared molded package structure 108 along multiple unit areas in each column of the lead frame panel array structure (e.g., along the illustrated second direction Y) using a mold with upper and lower portions that create tapered third and fourth sides 103 and 104 with the prospective lead portions extending outward from the sides 103 and 104 to facilitate subsequent lead trimming and forming as shown in the section view of FIG. 11B.

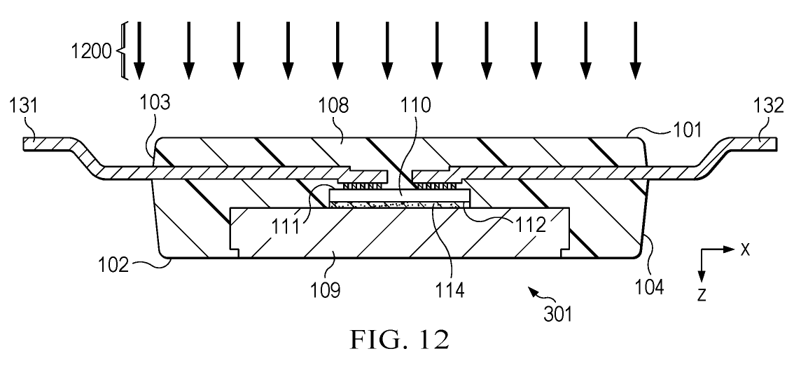

The method 200 continues at 220 in FIG. 2 with lead trimming and forming. FIG. 12 shows one example, in which a lead trimming and forming process 1200 is performed that trims and forms the prospective leads 131-134 in each unit area of the lead frame 301 (e.g., example leads 131 and 132 shown in the section view of FIG. 12). The illustrated example process 1200 trims exposed portions of the lead frame 301 to separate the leads 131-134 of adjacent unit areas and then forms the trimmed leads 131-134 into the gullwing shapes illustrated and described above in connection with FIGS. 1-1C. In other implementations, alternate forming operations can be used to form leads having different shapes (not shown).

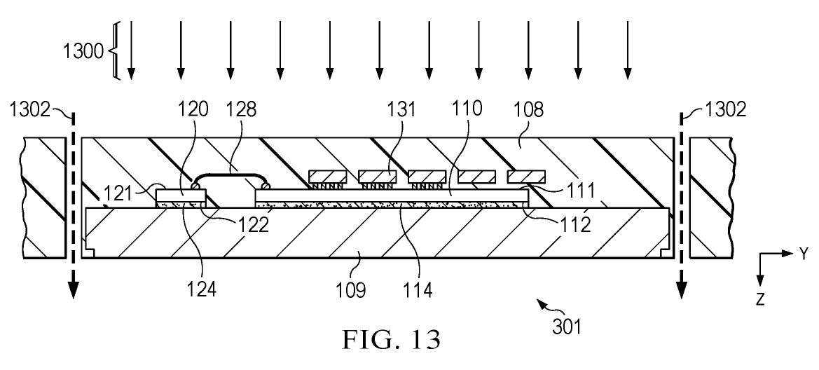

The example method 200 continues at 222 in FIG. 2 with package separation in order to separate individual packaged electronic devices 100 from the starting lead frame panel array structure 301. FIG. 13 shows one example, in which a package separation process 1300 is performed that separates adjacent electronic devices 100 from one another along lines 1302 in each column of the lead frame panel array structure. Any suitable package separation process can be used. In the illustrated example, the separation process 1300 includes laser or saw cutting along the lines 1302 between adjacent columns of unit areas of the starting lead frame panel array structure, for example, to cut through tie bars and other temporary support structures (not shown) of the starting lead frame 301.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a first semiconductor die having a first side, an opposite second side, and a first terminal along the first side, the second side of the first semiconductor die electrically connected to a conductive plate;
a second semiconductor die having a first side, an opposite second side, and a second terminal along the first side, the second side of the second semiconductor die electrically connected to the conductive plate; and
a bond wire that electrically connects the first and second terminals.

2. The electronic device of claim 1, wherein:
the first terminal is a first source terminal of the first semiconductor die;
the second terminal is a first input terminal of the second semiconductor die;
the first semiconductor die includes a bi-directional transistor with the first source terminal, a second source terminal along the first side of the first semiconductor die, and a first substrate connection to the second side of the first semiconductor die;
the second semiconductor die includes a current steering circuit having the first input terminal and a second input terminal along the first side of the second semiconductor die, and a second substrate connection to the second side of the second semiconductor die;
the bond wire is a first bond wire that electrically connects the first source terminal of the first semiconductor die to the first input terminal of the second semiconductor die; and
the electronic device comprises a second bond wire that electrically connects the second source terminal of the first semiconductor die to the second input terminal of the second semiconductor die.

3. The electronic device of claim 1, wherein the first semiconductor die includes gallium nitride and first semiconductor die includes silicon.

4. The electronic device of claim 1, wherein the second side of the first semiconductor die is attached to the conductive plate by a first conductive adhesive, and the second side of the second semiconductor die is attached to the conductive plate by a second conductive adhesive.

5. The electronic device of claim 1, comprising a package structure that encloses the first semiconductor die, the second semiconductor die and the bond wire.

6. The electronic device of claim 5, wherein a side of the conductive plate is exposed outside the package structure.

7. The electronic device of claim 1, wherein a terminal along the first side of the first semiconductor die is flip chip attached to a lead of the electronic device.

8. An electronic device, comprising:
a first semiconductor die having a gallium nitride substrate with a first side and an opposite second side attached to a conductive plate by a first conductive adhesive;
a second semiconductor die having a silicon substrate with a first side and an opposite second side attached to the conductive plate by a second conductive adhesive; and
an electrical connection between a first conductive feature on the first side of the first semiconductor die and a second conductive feature on the first side of the second semiconductor die.

9. The electronic device of claim 8, wherein the electrical connection includes a bond wire connected between the first conductive feature on the first side of the first semiconductor die and the second conductive feature on the first side of the second semiconductor die.

10. The electronic device of claim 8, wherein:
the first semiconductor die includes a transistor coupled to the first conductive feature on the first side of the first semiconductor die and having a first substrate connection to the second side of the first semiconductor die; and
the second semiconductor die includes a current steering circuit coupled to the second conductive feature on the first side of the second semiconductor die and having a second substrate connection to the second side of the second semiconductor die.

11. The electronic device of claim 10, wherein:
the transistor is a bi-directional transistor with a first source terminal and a second source terminal along the first side of the first semiconductor die;
the current steering circuit has a first input terminal and a second input terminal along the first side of the second semiconductor die; and
the electrical connection includes:
a first electrical connection between the first source terminal of the first semiconductor die and the first input terminal of the second semiconductor die; and
a second electrical connection between the second source terminal of the first semiconductor die and the second input terminal of the second semiconductor die.

12. The electronic device of claim 10, wherein the first electrical connection is a first bond wire, and the second electrical connection is a second bond wire.

13. A method of fabricating an electronic device, the method comprising:
attaching a first side of a first semiconductor die to a lead frame;
attaching a conductive plate to a second side of the first semiconductor die;
attaching a second side of a second semiconductor die to the conductive plate; and
forming an electrical connection between a first terminal along the first side of the first semiconductor die and a second terminal along a first side of the second semiconductor die.

14. The method of claim 13, wherein forming the electrical connection includes forming a bond wire between first terminal and the second terminal.

15. The method of claim 13, further comprising forming a package structure that encloses the first semiconductor die, the second semiconductor die and the electrical connection.

16. The method of claim 15, wherein a side of the conductive plate is exposed outside the package structure.

17. The method of claim 13, wherein attaching the first side of the first semiconductor die to the lead frame includes flip chip soldering a terminal along the first side of the first semiconductor die to the lead frame.

18. The method of claim 13, wherein:
the conductive plate is attached to the second side of the first semiconductor die by a first conductive adhesive; and
the second side of the second semiconductor die is attached to the conductive plate by a second conductive adhesive.

19. A system, comprising:
a circuit board; and
an electronic device mounted to the circuit board and comprising:
a first semiconductor die having a first side, an opposite second side, and a first terminal along the first side, the second side of the first semiconductor die electrically connected to a conductive plate;
a second semiconductor die having a first side, an opposite second side, and a second terminal along the first side, the second side of the second semiconductor die electrically connected to the conductive plate; and
a bond wire that electrically connects the first and second terminals.

20. The system of claim 19, comprising two instances of the electronic device connected in a half bridge grid tied converter circuit, each instance of the electronic device including a bidirectional transistor with two source terminals and two gate terminals.
